(19) United States
(12) Patent Application Publication
(10) Pub. No.: US 2017/0062375 A1
(43) Pub. Date: Mar. 2, 2017

(54) SEMICONDUCTOR DEVICE

(71) Applicant: SHARP KABUSHIKI KAISHA, Sakai City, Osaka (JP)

(72) Inventors: Etsuko ISHIZUKA, Sakai-shi (JP); Tomotoshi SATOH, Sakai-shi (JP); Hiroyuki NAKANISHI, Sakai-shi (JP)

(73) Assignee: Sharp Kabushiki Kaisha, Sakai-shi, Osaka (JP)

(21) Appl. No.: 15/118,576

(22) PCT Filed: Feb. 4, 2015
(86) PCT No.: PCT/JP2015/053098

§ 371 Date: Aug. 12, 2016

(30) Foreign Application Priority Data
Feb. 27, 2014 (JP) 2014-037325

(51) Int. Cl. H01L 23/00

(52) U.S. Cl. CPC H01L 24/49; H01L 24/05; H01L 24/45; H01L 2224/05553; H01L 2224/0603; H01L 2224/48091; H01L 2224/48247; H01L 2224/4903; H01L 2224/49113; H01L 2224/49431

(57) ABSTRACT

A GaN-based power device (1) includes a bonding pad portion (2) to which an aluminum wire (3) is bonded by ultrasonic bonding, and a second electrode (42) which is formed under the bonding pad (2). Ultrasonic vibration is applied such that an angle θ between a direction in which the ultrasonic vibration is applied to a wire and a length direction of the second electrode (42) is 0°≦θ≦45°.

### TECHNICAL FIELD

The present invention relates to a semiconductor device, and particularly to a semiconductor device which uses wire bonding.

### BACKGROUND ART

Recently, worldwide efforts to solve environmental issues have been made, and as the result, eco-friendly energy markets such as wind power generation or solar power generation have been expanded. In addition, markets of Asian countries around China have been further expanded. With the expansion of these markets, demand for power modules further increases.

In the power module, one semiconductor chip is electrically connected to another semiconductor chip, an inner lead, or the like by wire bonding which uses a metal wire. Here, when the metal wire is bonded to the semiconductor chip, a load to the semiconductor chip is a concern.

As a method for preventing the load, PTL 1 discloses a method for avoiding wire bonding to a power semiconductor element by bonding a metal wire to a chip electrode. In addition, a power semiconductor device disclosed in PTL 1 corresponds to a large current, and thus, an aluminum wire is used for wire bonding and the wire bonding is formed by ultrasonic wave or heat. Here, if the chip electrode is provided in an area different from the power semiconductor element, a size of the semiconductor device increases, and thus, a method of forming a chip electrode (bonding pad) on a power semiconductor element is proposed.

### CITATION LIST

### Patent Literature

PTL 1: Japanese Unexamined Patent Application Publication No. 2004-140072 (published on May 13, 2004)

### SUMMARY OF INVENTION

### Technical Problem

However, in a case where wire is bonded by applying ultrasonic vibration to a wire, in a structure of a semiconductor device including a bonding pad formed on a power semiconductor element and the power semiconductor element having a lower layer metal which is electrically connected to the bonding pad, the following problems appear.

In general, in a case where a wire is bonded while ultrasonic vibration is applied to the wire, a direction in which the wire is stretched is aligned with a direction to which ultrasonic vibration is applied. In this case, if a vibration direction of the ultrasonic vibration is approximately vertical to a length direction of a lower layer metal in a power semiconductor element, stress is applied to the power semiconductor element through a bonding pad at the time of bonding.

Therefore, interlayer cracking occurs between the bonding pad and the lower layer metal, in a portion where the bonding pad is not connected to the lower layer metal, and a short-circuit is generated due to the interlayer cracking. The aforementioned problems are a result of the interlayer cracking in the portion and the generation of the short-circuit due to the interlayer cracking.

The present invention is to solve the aforementioned problems, and an object thereof is to realize a manufacturing method which prevents cracking from occurring in a semiconductor element by a simple method when a semiconductor device is manufactured.

### Solution to Problem

In order to solve the above problems, a method of manufacturing a semiconductor device according to an aspect of the present invention includes an ultrasonic bonding process in which a wire is bonded to an upper layer metal formed on a semiconductor element while ultrasonic vibration is applied to the wire, in which the semiconductor element includes a lower layer metal that is formed under the upper layer metal, and in which the ultrasonic vibration is applied such that an angle θ between a direction in which ultrasonic vibration is applied to the wire and a length direction of the upper layer metal is 0°≦θ≦45°, in the ultrasonic bonding process.

### Advantageous Effects of Invention

According to one aspect of the present invention, there is an effect in which a manufacturing method that prevents cracking from occurring in a semiconductor element by a simple method can be realized, when a semiconductor device is manufactured.

### BRIEF DESCRIPTION OF DRAWINGS

FIG. 1 is a view illustrating a method of manufacturing a semiconductor device according to Embodiment 1 of the present invention, and is a sectional view taken along line A-A of FIG. 3(a).

FIG. 2(a) is a plan view illustrating a configuration of a semiconductor device according to Embodiment 1 of the present invention, and FIG. 2(b) is a side surface view of FIG. 2(a).

FIG. 3(a) is a plan view of a GaN-based power device of a semiconductor device according to Embodiment 1 of the present invention, and FIG. 3(b) is a view illustrating a contact electrode portion and is a perspective view illustrating a sectional view taken along line A-A of FIG. 3(a).

FIG. 4 is a perspective view of the contact electrode portion of the semiconductor device according to Embodiment 1 of the present invention.

FIG. 5(a) is a plan view of the contact electrode of the semiconductor device according to Embodiment 1 of the present invention, and FIG. 5(b) is a diagram illustrating an angle between a line direction of the contact electrode portion and an ultrasonic application direction.

FIG. 6 is a view illustrating a method of manufacturing a semiconductor device of the related art, and is a sectional view taken along line A-A of FIG. 3(a).

FIG. 7 is a plan view of a bonding pad portion of the semiconductor device according to Embodiment 1 of the present invention.

FIG. 8 is a plan view of a bonding pad portion of a semiconductor device according to Embodiment 2 of the present invention.

FIGS. 9(a) to 9(f) are plan views of a bonding pad portion of a semiconductor device according to Embodiment 3 of the present invention.

### DESCRIPTION OF EMBODIMENTS

Hereinafter, embodiments of the present invention will be described in detail with reference to accompanying drawings. A range of the present invention is not intended to limit only to dimensions, materials, shapes, relative dispositions, or the like of configuration components described in the respective embodiments, and the dimensions, the materials, the shapes, the relative dispositions, or the like thereof are just descriptions, as long as there is no specific description in particular.

### Embodiment 1

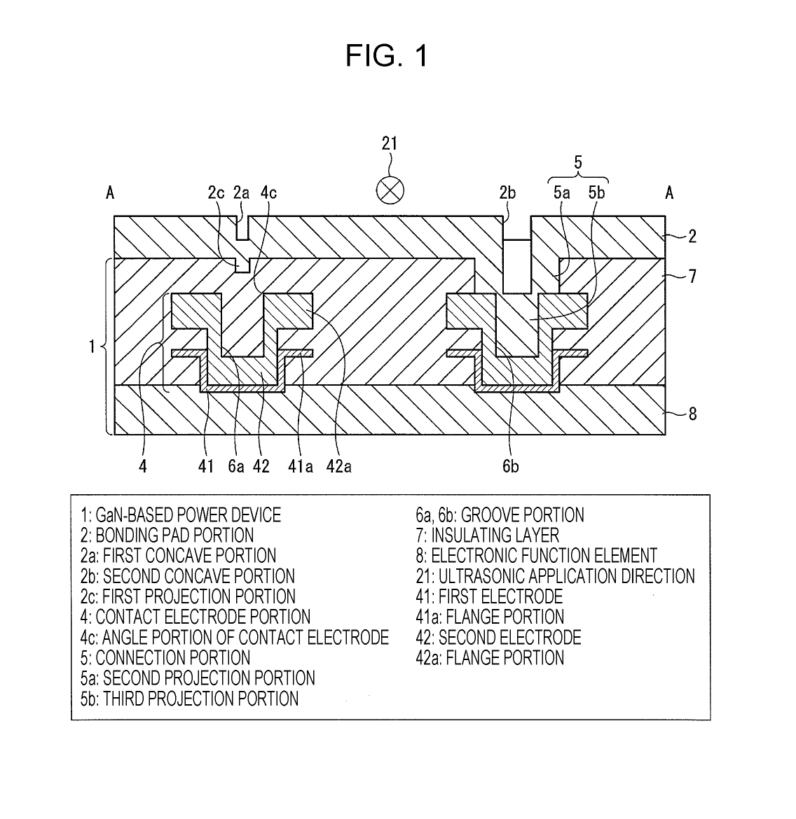

A method of manufacturing a semiconductor device 50 and the semiconductor device 50 according to Embodiment 1 of the present invention will be described with reference to FIG. 1 to FIG. 7.

### [Structure of Semiconductor Device 50]

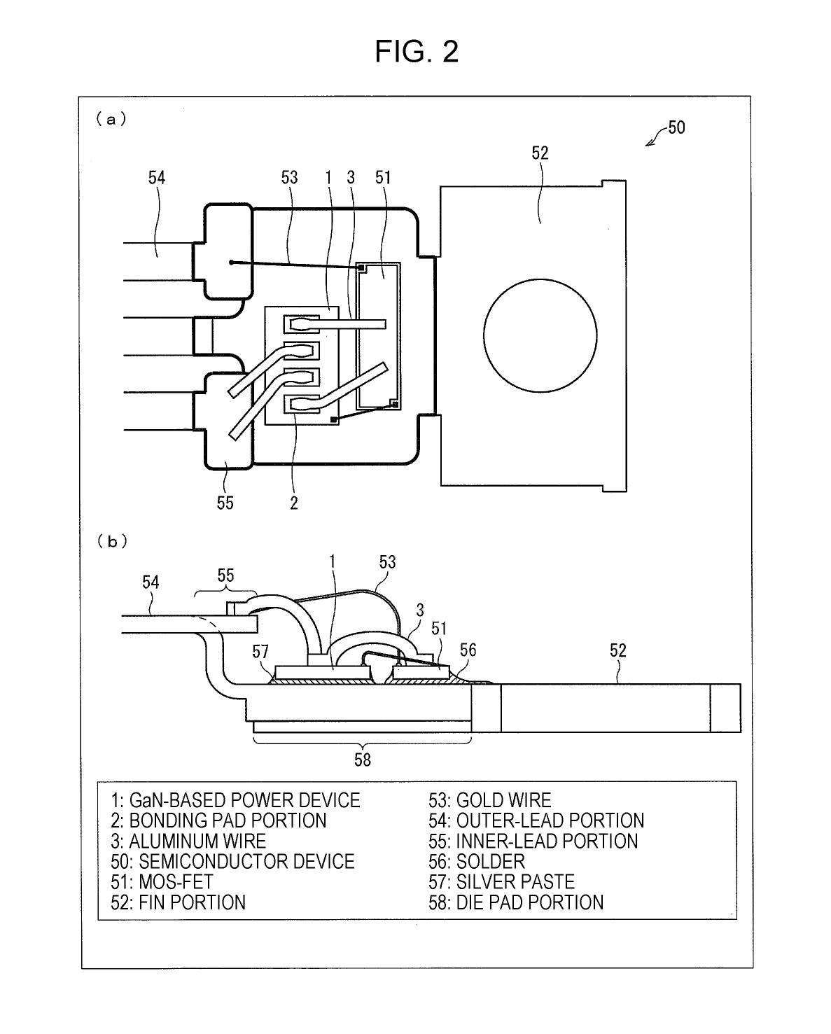

First, a structure of the semiconductor device 50 according to the present embodiment will be described with reference to FIG. 2(a) and FIG. 2(b). FIG. 2(a) is a plan view illustrating a configuration of the semiconductor device 50 according to Embodiment 1 of the present invention. FIG. 2(b) is a side surface view of FIG. 2(a).

The semiconductor device 50 includes a GaN-based power device 1 (semiconductor device, GaN-based semiconductor element), a bonding pad portion 2 (upper layer metal), an aluminum wire 3 (aluminum wire), MOS-FET 51, a pin portion 52, a gold wire 53, an inner-lead portion 55, a solder 56, a silver paste 57, and a die pad portion 58, as illustrated in FIG. 2(a) and FIG. 2(b).

The GaN-based power device 1 is mounted on the die pad portion 58 through the silver paste 57. The GaN-based power device 1 is electrically connected to the MOS-FET 51 by the aluminum wire 3 through the bonding pad portion 2. In addition, the GaN-based power device 1 is electrically connected to the inner-lead portion 55 by the aluminum wire 3 through the bonding pad portion 2. A current flowing to the bonding pad portion 2 from, for example, the GaN-based power device 1 flows to the inner-lead portion 55 or the MOS-FET 51 through the aluminum wire 3.

The MOS-FET 51 is mounted on the die pad portion 58 through the solder 56. In addition, the MOS-FET 51 is electrically connected to the inner-lead portion 55 by the gold wire 53. The MOS-FET 51 transmits a signal to the GaN-based power device 1, based on a signal from, for example, the inner-lead portion 55.

The inner-lead portion 55 is electrically connected to an outer-lead portion 54.

The outer-lead portion 54 is connected to the inner-lead portion 55. In addition, a part of the outer-lead portion 54 is directly connected to the die pad portion 58. The outer-lead portion 54 electrically connects the GaN-based power device 1 or the MOS-FET 51 to, for example, an external circuit through the inner-lead portion 55. In addition, the outer-lead portion 54 electrically connects the die pad portion 58 to, for example, an external circuit.

The pin portion 52 is formed as one-piece with the die pad portion 58, and is provided so as to be exposed outside a resin mold (not illustrated). Here, the resin mold is formed so as to cover, for example, the GaN-based power device 1, the bonding pad portion 2, the aluminum wire 3, the MOS-FET 51, the gold wire 53, the inner-lead portion 55, the solder 56, the silver paste 57, the die pad portion 58, and one terminal of the outer-lead portion 54. The pin portion 52 is provided to release heat of the GaN-based power device 1 and the MOS-FET 51, which are disposed on the die pad portion 58, to the outside.

In the present embodiment, a thickness of the die pad portion 58 in the semiconductor device 50 is formed to be substantially 1.27 mm. In addition, the MOS-FET 51 is mounted on the die pad portion 58 through the Pb—Ag—Cu-based high melting point solder 56 (substantially 40 W/m·k). In addition, the GaN-based power device 1 is mounted on the die pad portion 58 through the silver paste 57 (substantially 10 W/m·k).

In addition, the aluminum wire 3 and the gold wire 53 are used for electrical connection between the MOS-FET 51 and the GaN-based power device 1, electrically connection between the GaN-based power device 1 and the inner-lead portion 55, and electrically connection between the MOS-FET 51 and the inner-lead portion 55. Particularly, the aluminum wire 3 with a diameter of φ300 μm is used for a portion (a part of electrically connection between the MOS-FET 51 and the GaN-based power device 1, electrically connection between the GaN-based power device 1 and the inner-lead portion 55) through which a large current flows. The gold wire 53 with a diameter of φ30 μm is used for a portion (a part or the like of electrically connection between the MOS-FET 51 and the GaN-based power device 1) which is used for signal transmission or the like and a small current flows through.

### [Wiring Structure of Semiconductor Device 50]

A wiring structure of the semiconductor device 50 will be described with reference to FIG. 1 to FIG. 7.

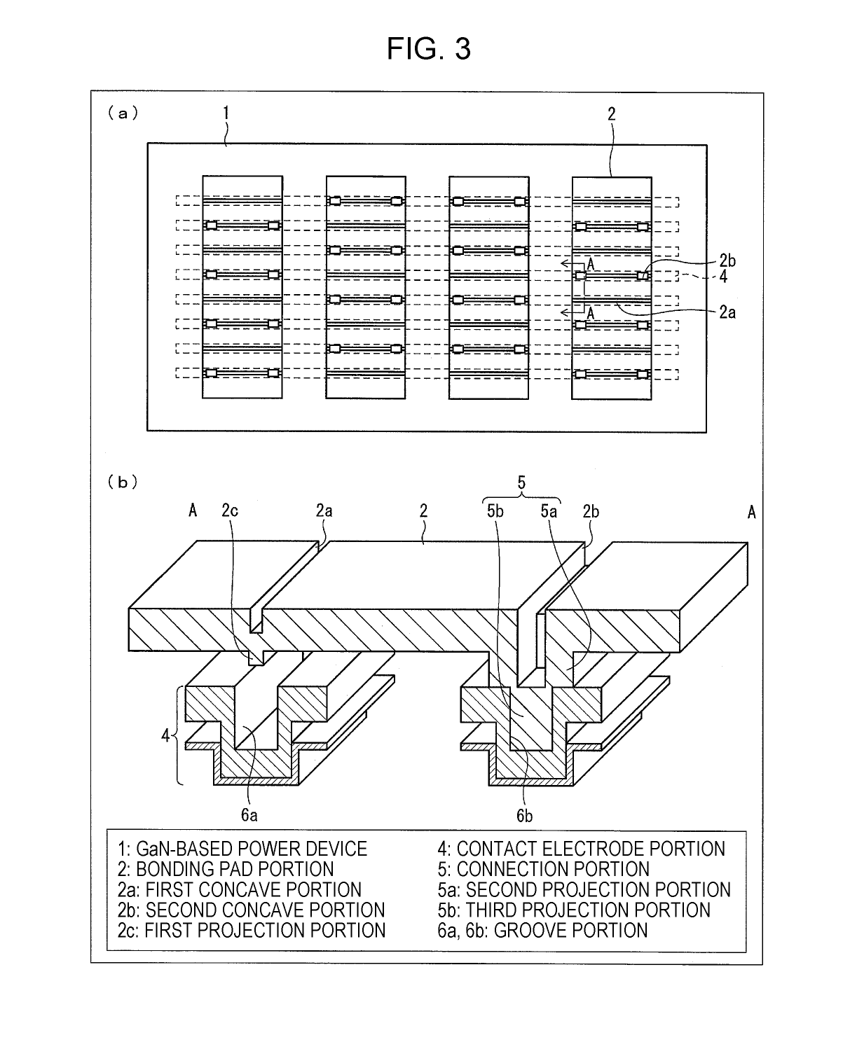

As illustrated in FIG. 1, the GaN-based power device 1 includes an electronic function element 8, a contact electrode portion 4, and an insulating layer 7 which are sequentially mounted. The bonding pad portion 2 is formed on the GaN-based power device 1. FIG. 1 is a view illustrating a method of manufacturing the semiconductor device 50, and is a sectional view taken along line A-A of FIG. 3(a). In addition, FIG. 3(a) is a plan view of the GaN-based power device 1 of the semiconductor device 50, and FIG. 3(b) is a view illustrating the contact electrode portion 4 and is a perspective view illustrating a sectional view taken along line A-A of FIG. 3(a).

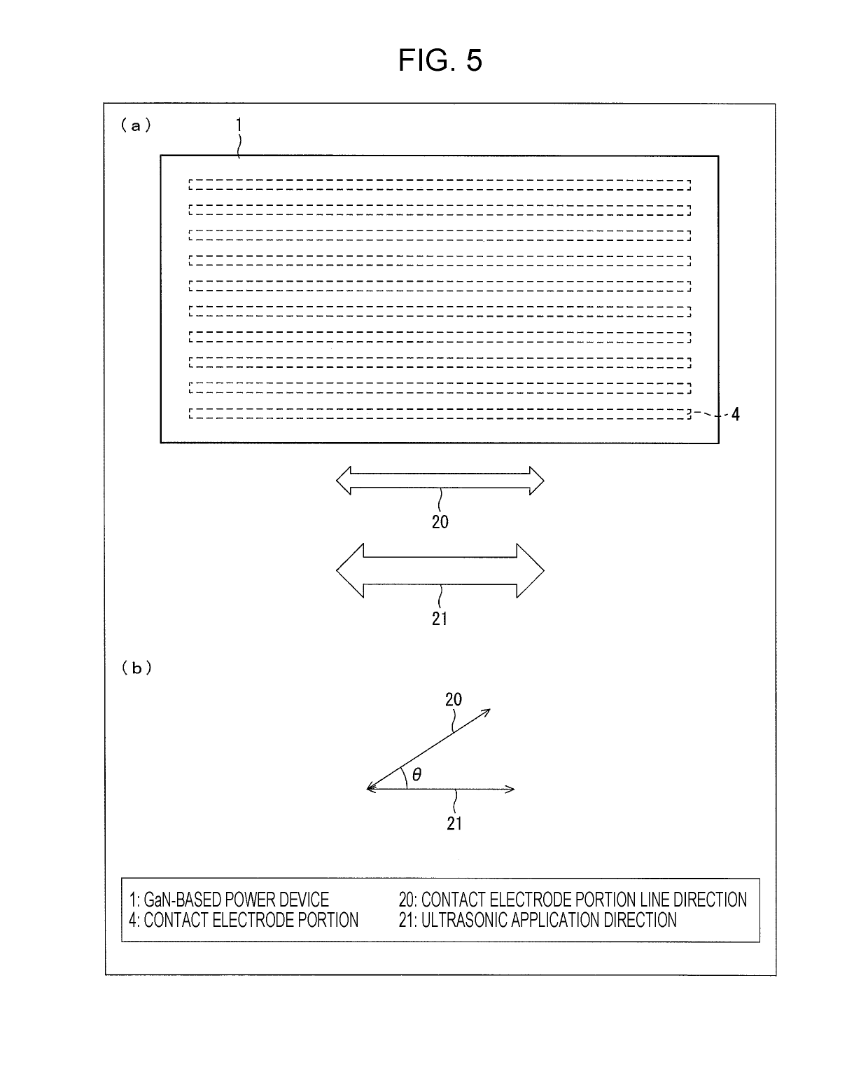

Specifically, the contact electrode portion 4 is plural, and forms on the electronic function element 8 so as to be parallel with each other. The insulating layer 7 is formed to cover the electronic function element 8 and the contact electrode portion 4. The bonding pad portion 2 is formed to cover the insulating layer 7. Here, the bonding pad portion 2 is placed on an upper side of the electronic function element 8. In addition, the contact electrode portion 4 is not viewed because the contact electrode portion 4 is covered with the insulating layer 7, and thus, the contact electrode portion 4 is denoted by a dotted line for the sake of convenient description, in FIG. 3(a) and FIG. 5(a) which will be described below.

The contact electrode portion 4 is electrically connected to the electronic function element 8. In addition, the contact electrode portion 4 is electrically connected to the bonding pad portion 2 at a predetermined location. The contact electrode portion 4 includes a first electrode 41 and a second electrode 42.

The first electrode 41 is formed to extend to a length direction (a front and back direction of paper in FIG. 1) of the GaN-based power device 1. A cross section of the first electrode 41 which is taken perpendicularly to a length direction of the GaN-based power device 1 is a substantially U-shaped section having a projection portion in a downward direction, as illustrated in FIG. 1. The first electrode 41 has flange portions 41a which protrude on an outer side in two portions of an upper end in a shape of the cross section illustrated in FIG. 1. The first electrode 41 is a thin film (for example, thickness is substantially 100 nm) which is configured with, for example, gold or tantalum, and functions as a barrier metal of a compound semiconductor in the GaN-based power device 1.

The second electrode 42 (lower layer metal) is formed to extend in the length direction of the GaN-based power device 1 along the first electrode 41. A cross section of the second electrode 42 taken perpendicularly to the length direction of the GaN-based power device 1 is a substantially U-shaped section having a projection portion in a downward direction, as illustrated in FIG. 1. In addition, the second electrode 42 has a groove portion 6a. Furthermore, a portion in which the contact electrode portion 4 is electrically connected to the bonding pad portion 2 includes a groove portion 6b. The second electrode 42 has flange portions 42a which protrude on an outer side in two portions of an upper end in a shape of the cross section illustrated in FIG. 1.

The first electrode 41 is formed such that a part of the first electrode 41 is buried on the electronic function element 8. A bottom surface of an outer side of the second electrode 42 and a part of a side surface of the outer side is in contact with an inner surface of the substantially U-shaped section of the first electrode 41, in the cross section illustrated in FIG. 1. A thickness of the second electrode 42 is greater than a thickness of the first electrode 41.

The bonding pad portion 2 (upper layer metal) includes a first concave portion 2a, a second concave portion 2b, and a first projection portion 2c. Furthermore, the bonding pad portion 2 includes a connection portion 5 in a portion in which the bonding pad portion 2 is electrically connected to the contact electrode portion 4. The connection portion 5 a second projection portion 5a and a third projection portion 5b. The bonding pad portion 2 is provided for bonding (wire bonding) of the aluminum wire 3. Furthermore, a current flows from the contact electrode portion 4 to the bonding pad portion 2, in the GaN-based power device 1.

The first concave portion 2a is formed on an upper portion of the groove portion 6a, in an upper surface of the bonding pad portion 2. The first projection portion 2c is formed over an upper portion of the groove portion 6a, in a lower surface of the bonding pad portion 2. The first projection portion 2c is formed to protrude toward a lower side. The first concave portion 2a and the first projection portion 2c are formed along the groove portion 6a. Since the groove portion 6a has a concave shape, the insulating layer 7 and the bonding pad portion 2, which are stacked on the groove portion, necessarily also have a concave shape. Accordingly, the bonding pad portion 2 includes the first concave portion 2a and the first projection portion 2c.

The second concave portion 2b is formed on an upper portion in which the contact electrode portion 4 is electrically connected to the bonding pad portion 2, that is, an upper portion of the connection portion 5, in an upper surface of the bonding pad portion 2. When the bonding pad portion 2 is formed, the connection portion 5 is simultaneously formed with the bonding pad portion 2 at a location where the contact electrode portion 4 is electrically connected to the bonding pad portion 2, after, for example, the groove portion 6b having a hole is formed in the insulating layer 7 by etching. Therefore, a depth of a concave portion of the second concave portion 2b is greater than a depth of a concave portion of the first concave portion 2a.

The second projection portion 5a is formed on an upper portion of the groove portion 6b, in a lower surface of the bonding pad portion 2. The second projection portion 5a is formed to protrude toward a lower side. The third projection portion 5b is formed on a lower surface of the second projection portion 5a so as to further protrude toward a lower surface.

The first projection portion 2c and the contact electrode portion 4 are not in contact with each other between the bonding pad portion 2 and the contact electrode portion 4. Therefore, the contact electrode portion 4 is not electrically connected to the bonding pad portion 2, and the insulating layer 7 is provided between the first projection portion 2c and the contact electrode portion 4.

In contrast to this, a lower surface of the second projection portion 5a comes into contact with an upper surface of the first cavity 42a, and furthermore, a lower surface and a side surface of the third projection portion 5b come into contact with the groove portion 6b. Therefore, in a portion where the connection portion 5 is formed in the bonding pad portion 2, the bonding pad portion 2 is electrically connected to the contact electrode portion 4, and the insulating layer 7 is not provided between the connection portion 5 and the contact electrode portion 4.

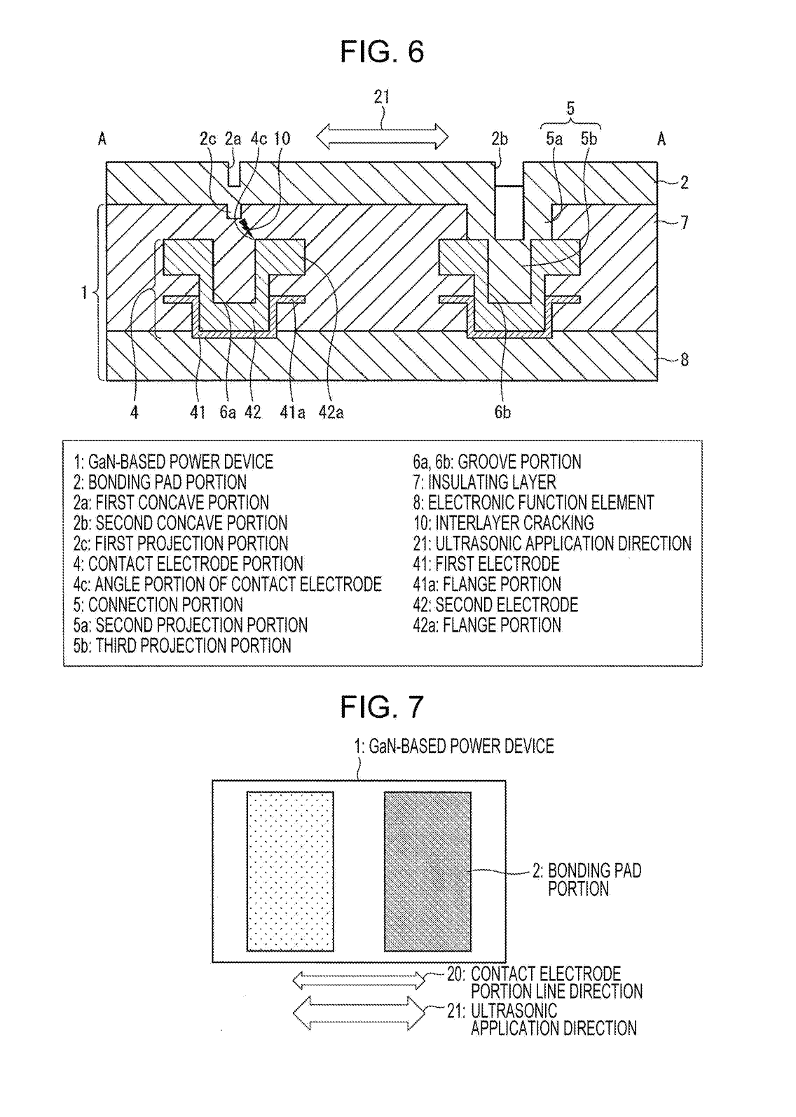

Here, in a case where the GaN-based power device 1 and the bonding pad portion 2 have the aforementioned configuration, when the bonding pad portion 2 is bonded to an inner-lead portion 55 or the MOS-FET 51 by ultrasonic bonding, using the aluminum wire 3, there is a possibility that interlayer cracking occurs in the GaN-based power device 1. Specifically, description will be made with reference to FIG. 3(a) and FIG. 6. FIG. 6 is a view illustrating a method of manufacturing a semiconductor device of the related art, and is a sectional view taken along line A-A of FIG. 3(a).

It is preferable that, in a case where the bonding pad portion 2 having an elongated shape is used, the bonding pad portion 2 is disposed as follows so as to make a current efficiently flow through a small metal wire from the contact electrode portion 4, in the semiconductor device 50. (1) A current flows from the contact electrode portion 4 to the bonding pad portion 2 to which the aluminum wire 3 is bonded. (2) As illustrated in FIG. 3(a), the bonding pad portion 2 is disposed in the GaN-based power device 1 so as to be orthogonal to the groove portion 6a (first concave portion 2a) including lots of the groove portions 6b (second concave portions 2b) which are formed in the contact electrode portion 4.

Here, a method of manufacturing the semiconductor device 50 uses ultrasonic bonding for bonding of the aluminum wire 3.

For wire-bonding which uses ultrasonic bonding, in general, for example, a substrate on which the GaN-based power device 1 is die-bonded is mounted on a fixed base of a an ultrasonic bonding device in a state where the bonding pad portion 2 faces up, a head portion of the ultrasonic bonding device adsorbing the substrate on which the GaN-based power device 1 is die-bonded the bonding pad portion 2 is rotated, and thereby, a direction in which the wire is stretched is aligned with a direction of ultrasonic vibration. In this state, a bonding wire (aluminum wire 3) which is supplied from the ultrasonic bonding device to the bonding pad portion 2 is pressed by the wedge tool of the ultrasonic bonding device, and bonding load (wedge pressure) is applied while ultrasonic vibration is applied. Thereby, impurity (oxide) of bonded surfaces are removed by friction of the ultrasonic vibration, a tensile strength of the wire is rapidly reduced by heat of the bonded surfaces which simultaneously occurs, plastic deformation occurs, and thus, the bonding pad portion 2 is bonded to the aluminum wire 3 (ultrasonic bonding process).

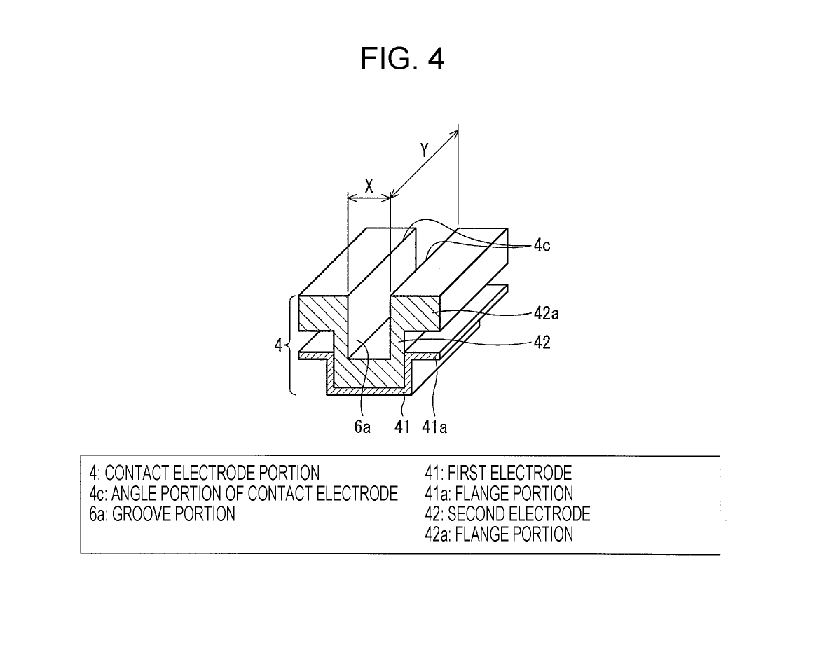

As described above, the direction in which the wire is stretched generally is aligned with a direction of ultrasonic vibration at the time of ultrasonic bonding, and thus, a connection portion of the aluminum wire 3 is parallel with a length direction of the bonding pad portion 2 (refer to FIG. 2(a)). As a result, an ultrasonic application direction 21 is perpendicular to a length direction of the contact electrode portion 4, as illustrated in FIG. 6. Here, the ultrasonic application direction 21 indicates a direction of ultrasonic direction at the time of ultrasonic bonding, and the length direction of the contact electrode portion 4 indicates a Y direction of FIG. 4. FIG. 4 is a perspective view of the contact electrode portion 4 of the semiconductor device 50 according to Embodiment 1 of the present invention.

In this way, in a case where the ultrasonic application direction 21 is orthogonal to the length direction of the contact electrode portion 4, stress is easily applied to a corner portion 4c of a contact electrode of the contact electrode portion 4, and there is a possibility that interlayer cracking 10 occurs, as illustrated in FIG. 6. As a result, there is a possibility that a short-circuit is generated due to the interlayer cracking 10 in the semiconductor device 50. Here, the corner portion 4c of the contact electrode of the contact electrode portion 4 indicates a side of an inner side of an upper surface of the second electrode of the contact electrode portion 4.

Particularly, in a case where the aluminum wire 3 thicker and harder than the gold wire 53 is used, a load to the corner portion 4c of the contact electrode at the time of wire-bonding increases, and there is a tendency that the interlayer cracking 10 occurs. In addition, a case where the ultrasonic application direction 21 is perpendicular to and close to the length direction of the contact electrode portion 4 also has the same results.

Here, the method of manufacturing the semiconductor device 50 according to the present embodiment is characterized in that the aluminum wire 3 is bonded to the bonding pad portion 2 by ultrasonic bonding such that the ultrasonic application direction 21 is substantially parallel with a contact electrode portion line direction 20, as illustrated in FIG. 5(a) and FIG. 5(b). FIG. 5(a) is a plan view of the contact electrode portion 4 of the semiconductor device 50 according to the present embodiment, and FIG. 5(b) is a diagram illustrating an angle θ between the contact electrode portion line direction 20 and the ultrasonic application direction 21.

The substantial parallel indicates that the contact electrode portion line direction 20 is parallel with the ultrasonic application direction 21, or that the angle θ between the contact electrode portion line direction 20 and the ultrasonic application direction 21 is −45°≦θ≦45°, in a case where the ultrasonic application direction 21 is used as a reference. Here, when the angle θ between the contact electrode portion line direction 20 and the ultrasonic application direction 21 is considered, either the contact electrode portion line direction 20 or the ultrasonic application direction 21 may be a reference, that is, the substantial parallel indicates that the angle θ (magnitude of the angle θ which is formed between the contact electrode portion line direction 20 and the ultrasonic application direction 21) between the contact electrode portion line direction 20 and the ultrasonic application direction 21 is 0°≦θ≦45°. The contact electrode portion line direction 20 indicates the length direction of the contact electrode portion 4.

Specifically, in FIG. 4, if a length of a width direction of the groove portion 6a is denoted by X and a length in an extending direction of the groove portion 6a is denoted by Y (1<Y/X), the extending direction (contact electrode portion line direction 20) is substantially parallel with the ultrasonic application direction 21 at the time of ultrasonic bonding, and thus, it is possible to prevent the interlayer cracking 10 from occurring.

At this time, if the bonding pad portion 2 is noted, a length direction of the bonding pad portion 2 is substantially perpendicular to the contact electrode portion line direction 20 and the ultrasonic application direction 21, as illustrated in FIG. 7. FIG. 7 is a plan view of the bonding pad portion 2 of the semiconductor device 50 according to present embodiment.

According to the aforementioned configuration, the ultrasonic application direction 21 is substantially parallel with the contact electrode portion line direction 20. Therefore, stress to the corner portion 4c of the contact electrode is released, and the interlayer cracking 10 which easily occurs in the insulating layer 7 can be prevented from occurring. As a result, it is possible to prevent a short-circuit from being generated due to the interlayer cracking 10. In addition, in the method of manufacturing the semiconductor device 50 according to the present embodiment obtains effects in which a simple change such as a change of a vibration direction of a wedge tool may be made, procurement of a manufacturing device and a new member is not required, and products with higher reliability can be manufactured with low cost.

As described above, the method of manufacturing the semiconductor device 50 according to the present embodiment is characterized in that the ultrasonic application direction 21 is substantially parallel with the contact electrode portion line direction 20, for example, when the GaN-based power device 1 is connected to other terminals by ultrasonic bonding, in the GaN-based power device 1 including the contact electrode portion 4 formed on the electronic function element 8.

In other words, the method of manufacturing the semiconductor device 50 according to the present embodiment is characterized in that the ultrasonic application direction 21 is substantially parallel with the contact electrode portion line direction 20 when ultrasonic bonding of the aluminum wire 3 is formed to the bonding pad portion 2 so as to electrically couple the bonding pad portion 2 to the inner-lead portion 55 or the MOS-FET 51.

### Verification Example

A verification example of the method of manufacturing the semiconductor device 50 according to the present embodiment will be described below. In the present verification example, an example in which a case where the aluminum wire 3 is bonded to the bonding pad portion 2 is embodied will be described with conditions of following (1) to (3). (1) The bonding pad portion 2 which is formed on the GaN-based power device 1 is set to substantially 600 μm×1200 μm. (2) The aluminum wire 3 is set to 0300 μm. (3) Wire bonding is formed by ultrasonic bonding in which load is set to 700 g.

As a result, in a case where ultrasonic vibration is applied such that the ultrasonic application direction 21 is substantially perpendicular to the contact electrode portion line direction 20, the interlayer cracking 10 starting from the corner portion 4c of the contact electrode occurs between the bonding pad portion 2 and the contact electrode portion 4.

Meanwhile, it was confirmed that, in a case where the ultrasonic vibration is applied such that the ultrasonic application direction 21 is substantially parallel with the contact electrode portion line direction 20, the interlayer cracking 10 does not occur.

In addition, a first side of the bonding wire is set to the GaN-based power device 1 side (bonding pad portion 2 side), and thereby it is possible to further reduce a load to the GaN-based power device 1 at the time of ultrasonic bonding, and to prevent the interlayer cracking 10 from occurring.

In addition, since the corner portion 4c of the contact electrode easily becomes a starting point, the contact electrode portion 4 is tapered from a bottom of the groove portion 6a toward the corner portion 4c of the contact electrode without making a shape of the contact electrode portion 4 in a rectangular shape, and thus, a load to the corner portion 4c of the contact electrode at the time of ultrasonic bonding can be reduced. Therefore, it is possible to prevent the interlayer cracking 10 from occurring.

Here, a material or a shape of the GaN-based power device 1 itself is not limited. In addition, a target which is connected to the GaN-based power device 1 by wire bonding is not limited to the inner-lead portion 55 and the MOS-FET 51, and may be the die pad portion 58, other chip terminals, or the like. A connection destination is not limited. The number of the GaN-based power device 1 which is mounted on the semiconductor device 50 is not limited if the number is at least one. In addition, a wire to be used may be configured with gold, silver, copper, aluminum, or the like, and a material or a diameter of the wire is not limited. Generally, the outer-lead portion 54 and the inner-lead portion 55 can use pure copper, Ag plated products, or the like, but materials thereof are not also limited.

In the present embodiment, a direction in which the contact electrode portion 4 extends is a length direction of the GaN-based power device 1, but is not limited to this. The contact electrode portion line direction 20 at the time of ultrasonic bonding may be substantially parallel with the ultrasonic application direction 21.

In addition, as the ultrasonic application direction 21 is substantially parallel with the contact electrode portion line direction 20, the ultrasonic application direction 21 is substantially parallel with a length direction of the groove portion 6a. Thereby, when ultrasonic bonding is formed, a load of the stress which is applied to the groove portion 6a of the contact electrode portion 4 and the first projection portion 2c of the bonding pad portion 2 is reduced, and the interlayer cracking 10 can be prevented from occurring. Detailed description will be made below.

The groove portion 6a is a hallow portion which is formed when the contact electrode portion 4 is formed. After the contact electrode portion 4 is formed, the groove portion 6a is filled with the insulating layer 7, and the bonding pad portion 2 is formed thereon. Thereafter, the first projection portion 2c having a projection shape toward the groove portion 6a is formed at a location facing the groove portion 6a in the bonding pad portion 2. In a process of manufacturing a semiconductor device of the related art, it can be seen a tendency that the interlayer cracking 10 easily occurs due to the groove portion 6a and the first projection portion 2c which are formed in the contact electrode portion 4, at the time of ultrasonic bonding.

Here, ultrasonic vibration is applied such that a length direction of the groove portion 6a is substantially parallel with the ultrasonic application direction 21, based on the method of manufacturing the semiconductor device 50 according to the present embodiment, when ultrasonic bonding is formed. Thereby, when the ultrasonic bonding is formed, a load of the stress which is applied to the groove portion 6a and the first projection portion 2c is reduced, and the interlayer cracking 10 can be prevented from occurring. As a result, it is possible to prevent a short-circuit from being generated due to the interlayer cracking 10 which easily occurs in the insulating layer 7.

### Embodiment 2

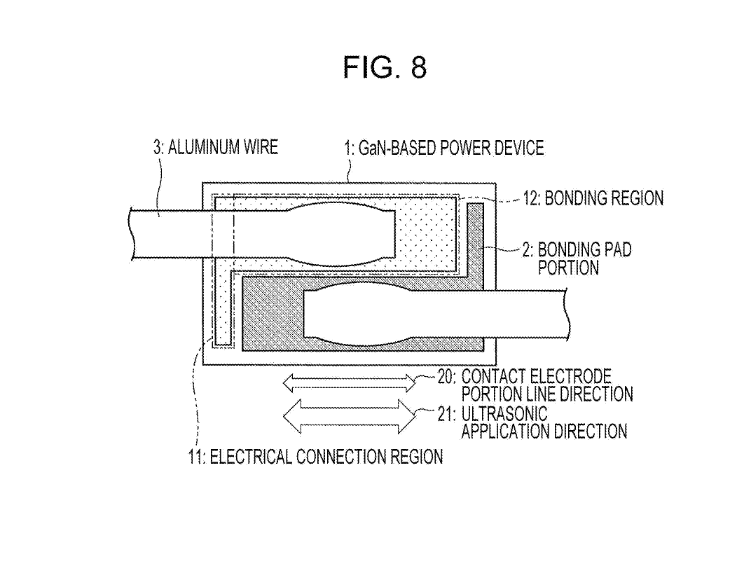

Another embodiment of the present invention will be described with reference to FIG. 7 and FIG. 8 as follows. FIG. 8 is a plan view of the bonding pad portion 2 of the semiconductor device 50 according to the present embodiment.

The bonding pad portion 2 of the semiconductor device 50 according to Embodiment 1 has a rectangular shape as illustrated in FIG. 7.

In contrast to this, a shape of the bonding pad portion 2 of the semiconductor device 50 according to the present embodiment includes a wide portion (wide-width region) and a narrow portion (narrow-width region) in contact electrode portion line direction 20 and the ultrasonic application direction 21. In the bonding pad portions 2 adjacent to each other, the narrow-width region of one bonding pad portion 2 faces the wide-width region of the other bonding pad portion 2 in a length direction of the lower layer metal (second electrode 42), and the wide-width region of one bonding pad portion 2 faces the narrow-width region of the other bonding pad portion 2 in the length direction of the lower layer metal. In addition, the aluminum wire 3 is bonded to the wide portion so as to be substantially parallel with the length direction of the bonding pad portion 2.

In other words, the semiconductor device 50 according to the present embodiment includes two bonding pad portions 2. The GaN-based power device 1 includes multiple contact electrode portions 4 parallel with each other. Each of the two bonding pad portions 2 includes an electrical connection region 11 (electrical connection portion) disposed across all of the multiple contact electrode portions 4 in an ultrasonic orthogonal direction which is a direction perpendicular to an application direction of the ultrasonic vibration. In addition, each of the two bonding pad portions 2 includes a bonding region 12 (bonding portion) included in which a length of the ultrasonic orthogonal direction is less than the electrical connection region 11 and greater than a diameter of the aluminum wire 3. Furthermore, the bonding region 12 of the one bonding pad portion 2 and the bonding region 12 of the other bonding pad portion 2 are arranged side by side in the ultrasonic orthogonal direction.

According to the configuration, a direction (hereinafter, referred to as a bonding direction of the aluminum wire 3) in which the aluminum wire 3 is bonded to the bonding pad portion 2 can be substantially parallel with the contact electrode portion line direction 20. Therefore, when the ultrasonic bonding is formed, the ultrasonic vibration can be applied to be substantially parallel with the contact electrode portion line direction 20 without difficulty. As a result, a wedge tool can be prevented from being bent. In addition, by employing the configuration, the aluminum wire 3 can be prevented from deviating from the bonding pad portion 2 due to collapse in a length direction. Detailed description will be made below. In detail, description will be made below.

In Embodiment 1, a bonding direction of the aluminum wire 3 is substantially perpendicular to the ultrasonic application direction 21, as illustrated in FIG. 2(a) and FIG. 7. Here, force from the wedge tool is easily applied in a length direction of the aluminum wire 3 during the ultrasonic bonding. Therefore, in the manufacturing method according to Embodiment 1 in which the ultrasonic vibration being applied to the aluminum wire 3 by the wedge tool perpendicularly is applied in the length direction of the aluminum wire 3, excessive stress is applied between the aluminum wire 3 and the wedge tool. As a result, there is a possibility that, for example, flapping of the wedge tool increases and the wedge tool bends.

In addition, in a case where the ultrasonic vibration is applied to the aluminum wire 3 during the ultrasonic bonding, the aluminum wire 3 collapses in the ultrasonic application direction 21. Therefore, in Embodiment 1, if the ultrasonic vibration is applied to the aluminum wire 3, the aluminum wire 3 collapses in a diameter direction of the aluminum wire 3. Therefore, there is a possibility that the aluminum wire 3 which collapses in the diameter direction deviates from the bonding pad portion 2. Therefore, in the method of manufacturing the semiconductor device 50 according to Embodiment 1, it is necessary to take action so as not to make the aluminum wire 3 deviate from the bonding pad portion 2, such as an increase of the bonding pad portion 2.

In the present embodiment, as the bonding direction of the aluminum wire 3 is substantially parallel with the contact electrode portion line direction 20, the bonding direction of the aluminum wire 3 is substantially parallel with the ultrasonic application direction 21. According to the configuration, it is possible to apply the ultrasonic vibration to the aluminum wire 3 without applying excessive stress to the aluminum wire 3 from the wedge tool. As a result, the wedge tool can be prevented from being bent.

In addition, according to the configuration, when the ultrasonic bonding is formed, the aluminum wire 3 collapses in the length direction of the aluminum wire 3, and thus, it is possible to prevent the aluminum wire 3 from deviating from the bonding pad portion 2.

In addition, the bonding pad portion 2 to which a current flows from the contact electrode portion 4 crosses all the multiple contact electrode portions 4, in the GaN-based power device 1, and an area thereof is large. Accordingly, the current can efficiently flow through a small metal wire from the contact electrode portion 4.

### Embodiment 3

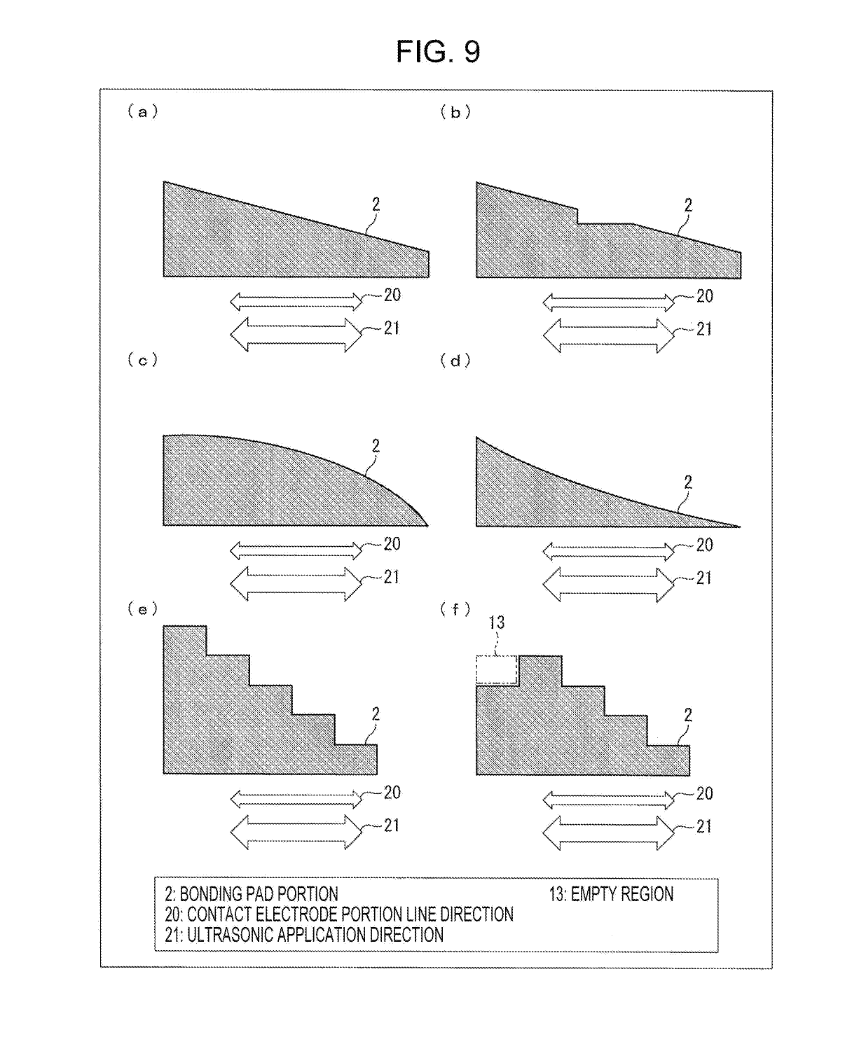

Embodiment 3 of the present invention will be described with reference to FIG. 9(a) to FIG. 9(f) as follows. FIG. 9(a) to FIG. 9(f) are plan views of the bonding pad portion 2 of the semiconductor device 50 according to present embodiment.

The bonding pad portion 2 of the semiconductor device 50 according to Embodiment 1 has a rectangular shape as illustrated in FIG. 7.

In contrast to this, the bonding pad portion 2 of the semiconductor device 50 according to the present embodiment includes the connection portion 5 which is electrically connected to any one of the contact electrode portions 4. Furthermore, the higher the total number of the connection portions 5 aligned in the ultrasonic orthogonal direction is, the greater the widths of the electrical connection region 11 and the bonding region 12 of each of the bonding pad portions 2 in the ultrasonic orthogonal direction are.

According to the configuration, it is possible to obtain effects in which a density of a current flowing from the contact electrode portion 4 can be smoothed, electrical loss can be reduced, and electricity can be efficiently taken out. Description will be made below in detail.

The bonding pad portion 2 illustrated in FIG. 9(a) is one of the bonding pad portions 2 which are provided in the GaN-based power device 1. The bonding pad portion 2 illustrated in FIG. 9(a) makes a pair with the bonding pad portion 2 having a shape obtained by rotating the bonding pad portion 180 degrees around a midpoint of a hypotenuse of the bonding pad portion 2 illustrated in FIG. 9(a), and is disposed on the GaN-based power device 1. A rectangular shape is formed by combining the pair of two bonding pad portions 2. The bonding pad portions 2 making a pair are respectively bonded to the aluminum wires 3 by ultrasonic bonding such that bonding directions of the aluminum wires 3 are substantially parallel with the contact electrode portion line direction 20. At this time, the pair of bonding pad portions 2 is formed to have a shape which does not interfere with the aluminum wire 3.

A current flowing from the contact electrode portion 4 through the connection portion 5 increases in accordance with an increase of portions (connection portions 5) which are electrically connected to the bonding pad portion 2. Hence, even if the portions (connection portion 5) which are electrically connected increase, a current density increase if areas of the bonding pad portions 2 are constant. Here, as the total number of the bonding pad portions 2 of the connection portions 5 in a direction perpendicular to the contact electrode portion line direction 20 increases, a width of the bonding pad portion 2 according to the present embodiment in the direction increases.

Specifically, description will be made with reference to FIG. 9(a). A current from the contact electrode portion 4 flows from the right of paper toward the left of the paper, in the bonding pad portion 2. In addition, the total number of the connection portions 5 of the bonding pad portion 2 increases from the right of the paper toward the left of the paper. In the present embodiment, the width of the bonding pad portion 2 in a direction perpendicular to the contact electrode portion line direction 20 also increases from the right of the paper toward the left of the paper, in accordance with an increase of the total number of the connection portions 5 a lower portion. According to the configuration, a density of a current flowing through the bonding pad portion 2 is substantially constant, and the current density is smoothed.

FIG. 9(b) to FIG. 9(e) are examples of shapes of the bonding pad portion 2 of the semiconductor device 50 according to the present embodiment, and illustrate a case where the shapes of the bonding pad portion 2 include a circular arc shape, a slide shape, and a stepwise shape, or there is roughness in a part of each of the shapes. The shape of the bonding pad portion 2 may increase toward an endmost line of each contact electrode portion line, when viewed macroscopically, and a pad shape thereof is not limited.

In addition, for example, an empty region 13 may be formed between the two bonding pad portions 2, and a new bonding pad portion may be provided in the empty region.

### [Summarizing]

A method of manufacturing the semiconductor device (50) according to a first aspect of the present invention includes an ultrasonic bonding process in which a wire (aluminum wire 3) is bonded to an upper layer metal (bonding pad portion 2) formed on a semiconductor element (GaN-based power device 1) while ultrasonic vibration is applied to the wire, the semiconductor element a lower layer metal (second electrode 42) that is formed under the upper layer metal, and the ultrasonic vibration is applied such that an angle θ between a direction in which ultrasonic vibration is applied to the wire and a length direction of the upper layer metal is 0°≦θ≦45°, in the ultrasonic bonding process.

According to the configuration, the ultrasonic vibration is applied to be substantially parallel (an angle θ between a direction in which the ultrasonic vibration is applied to the wire and a length direction of the lower layer metal is 0°≦θ≦45°) with the length direction of the lower layer metal. Therefore, stress to the corner portion of the contact electrode is released, and the interlayer cracking can be prevented from occurring. As a result, it is possible to prevent a short-circuit from being generated due to the interlayer cracking which easily occurs in the insulating layer. Therefore, it is possible to realize a manufacturing method which can prevent cracking of a semiconductor element by using a simple method when the semiconductor device is manufactured. In addition, effects are obtained in which procurement of a manufacturing device and a new member is not required, and products with higher reliability can be manufactured with low cost.

In the method of manufacturing the semiconductor device (50) according to a second aspect of the present invention described in the first aspect, the semiconductor element (GaN-based power device 1) may be a GaN-based semiconductor element, and the wire (aluminum wire 3) may be an aluminum wire.

According to the configuration, the GaN-based semiconductor element is used for the semiconductor element. Therefore, a power semiconductor device can be manufactured. In addition, an aluminum wire is used for the wire. Therefore, the wire can make a large current flow through.

In the method of manufacturing the semiconductor device (50) according to a third aspect of the present invention described in the first or second aspect, the lower layer metal (second electrode 42) may include a concave portion, and the upper layer metal (bonding pad portion 2) may include a projection portion (first projection portion 2c) that protrudes toward the concave portion at a location facing the concave portion.

According to the configuration, in the process of manufacturing the semiconductor device, even if a concave shape is formed in a lower layer metal, and a projection shape is formed toward the lower layer metal at a location facing the concave shape of the lower layer metal of an upper layer metal, stress applied to the projection shape of the upper layer metal and the concave shape of the lower layer metal when the ultrasonic bonding is formed is reduced, and interlayer cracking can be prevented from occurring. As a result, it is possible to prevent a short-circuit from being generated due to the interlayer cracking which easily occurs in an insulating layer.

In a semiconductor device (50) that is manufactured by the method of manufacturing a semiconductor device according to a fourth aspect of the present invention described in any one of the first to third aspects, the semiconductor device (50) may include the semiconductor element (GaN-based power device 1) and the two upper layer metals (bonding pad portions 2); the semiconductor element may include the multiple lower layer metals (second electrodes 42); each of the two upper layer metals may include an electrical connection portion (electrical connection region 11) that is disposed to cross all of the multiple lower layer metals in an ultrasonic orthogonal direction which is a direction perpendicular to an application direction of the ultrasonic vibration, and a bonding portion (bonding region 12) in which a length of the ultrasonic orthogonal direction is less than the electrically connection portion and greater than a diameter of the wire (aluminum wire 3); and the bonding portion of one of the upper layer metals and the bonding portion of the other of the upper layer metals may be disposed to be aligned in the ultrasonic orthogonal direction.

According to the configuration, a bonding direction of a wire in an upper layer metal can be substantially parallel with a length direction of a lower layer metal. Therefore, when ultrasonic bonding is formed, ultrasonic vibration can be applied to be substantially parallel with a length direction of a lower layer metal without occurring excessive stress. Thereby, a wedge tool can be prevented from being bent. In addition, according to the configuration, it is possible to prevent the aluminum wire 3 from deviating from the bonding pad portion 2 due to collapse in a length direction.

In the method of manufacturing the semiconductor device (50) according to a fifth aspect of the present invention described in the fourth aspect, the upper layer metal (bonding pad portion 2) may include a connection portion (5) that is electrically connected to any one of the lower layer metals (second electrode 42), and

wherein the higher the total number of the connection portions aligned in the ultrasonic orthogonal direction is, the greater the lengths of the electrically connection portion (electrical connection region 11) and the bonding portion (bonding region 12) of each of the upper layer metals in the ultrasonic orthogonal direction are.

According to the configuration, a density of a current flowing from a lower layer metal in an upper layer metal can be smoothed, and thus, electrical loss can be reduced, and electricity can be efficiently taken out.

The present invention is not limited to the respective embodiments, various modifications can be made by the scope of claims, and an embodiment obtained by appropriately combining technical means which are respectively disclosed in other embodiments is also included in a technical range of the present invention. Furthermore, novel technical characteristics can be formed by combining technical means which are respectively disclosed in the respective embodiments.

### INDUSTRIAL APPLICABILITY

The present invention can be used as a method of manufacturing a semiconductor device, and particularly, can be used for a method of manufacturing a semiconductor device which uses ultrasonic bonding for wire bonding.

### REFERENCE SIGNS LIST

1 GaN-BASED POWER DEVICE (SEMICONDUCTOR ELEMENT)
2 BONDING PAD PORTION (UPPER LAYER METAL)
2a FIRST CONCAVE PORTION
2b SECOND CONCAVE PORTION
2c FIRST PROJECTION PORTION (PROJECTION PORTION)
3 ALUMINUM WIRE
4 CONTACT ELECTRODE PORTION
4c CORNER PORTION OF CONTACT ELECTRODE
5 CONNECTION PORTION
5a SECOND PROJECTION PORTION
5b THIRD PROJECTION PORTION
6a, 6b GROOVE PORTION
7 INSULATING LAYER
8 ELECTRONIC FUNCTION ELEMENT
10 INTERLAYER CRACK
11 ELECTRICAL CONNECTION REGION (ELECTRICAL CONNECTION PORTION)
12 BONDING REGION (BONDING PORTION)
13 EMPTY REGION
20 CONTACT ELECTRODE PORTION LINE DIRECTION
21 ULTRASONIC APPLICATION DIRECTION
41 FIRST ELECTRODE
41a FLANGE PORTION
42 SECOND ELECTRODE (LOWER LAYER METAL)
42a FLANGE PORTION
50 SEMICONDUCTOR DEVICE
51 MOS-FET
52 PIN PORTION
53 GOLD WIRE
54 OUTER-LEAD PORTION
55 INNER-LEAD PORTION
56 SOLDER
57 SILVER PASTE
58 DIE PAD PORTION

1-3. (canceled)

4. A semiconductor device
comprising:
a semiconductor element; and
two upper layer metals which are formed on the semiconductor element and to each of which a wire is bonded,
the semiconductor element including multiple lower layer metals which are formed right under each of the two upper layer metals and which extend in parallel in a first direction,
each of the two upper layer metals including an electrical connection portion that is disposed to cross all of the multiple lower layer metals in a second direction perpendicular to the first direction, and a bonding portion in which a length of the second direction is less than the electrical connection portion and greater than a diameter of the wire, and
the bonding portion of one of the upper layer metals and the bonding portion of the other of the upper layer metals being disposed to be aligned in the second direction.

5. The semiconductor device according to claim 4,
wherein the upper layer metal includes a connection portion that is electrically connected to any one of the lower layer metals, and
wherein the higher the total number of the connection portions aligned in the second direction is, the greater the lengths of the electrical connection portion and the bonding portion of each of the upper layer metals in the second direction are.
